(19) United States
(12) Patent Application Publication
(10) Pub. No.: US 2006/0249742 A1
(43) Pub. Date: Nov. 9, 2006

(54) Light emitting device for achieving uniform light distribution and backlight unit employing the same

(75) Inventors: Ji-whan Noh, Suwon-si (KR); Jong-min Wang, Seongnam-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/319,711

(22) Filed: Dec. 29, 2005

(30) Foreign Application Priority Data
May 4, 2005 (KR) 10-2005-0037470

(51) Int. Cl. H01L 33/00

(52) U.S. Cl. 257/98

(57) ABSTRACT

A light emitting device for achieving uniform light distribution and a backlight unit employing the light emitting device. The light emitting device includes: a light reflecting member having light reflecting surfaces by which light is reflected; a light transmitting member formed on the light reflecting surfaces of the light reflecting member and having light emitting surfaces; and a point light source emitting light to the light transmitting member. The light emitting surfaces of the light transmitting member through which light incident from the point light source is emitted include: a flat directly emitting surface facing the point light source, and directly passing light emitted from the point light source to the outside of the light transmitting member; and a curved totally reflecting surface formed around the directly emitting surface, and totally reflecting light emitted from the point light source to the light reflecting member and passing light reflected by the light reflecting member to the outside of the light transmitting member.

### CROSS-REFERENCE TO RELATED PATENT APPLICATION

This application claims priority from Korean Patent Application No. 10-2005-0037470, filed on May 4, 2005, in the Korean Intellectual Property Office, the disclosure of which is incorporated herein in its entirety by reference.

### BACKGROUND OF THE INVENTION

1. Field of the Invention

The present invention relates to a light emitting device for achieving uniform light distribution and a backlight unit employing the same and, more particularly, to a light emitting device for uniformly emitting light only to a specific region and a direct lighting type backlight unit employing the light emitting device.

2. Description of the Related Art

Liquid crystal displays (LCDs), a type of flat panel display, are non-emissive displays that cannot emit light themselves but receive external light to form an image. In this case, backlight units are installed at a rear side of the LCDs to emit light. Cold cathode fluorescent lamps (CCFLs) have been mainly used as light sources for backlight units of LCDs. Recently, backlight units using point light sources like light emitting diodes (LED) instead of CCFLs have been developed. Backlight units using point light sources like the LEDs have a higher color gamut and a longer lifespan than backlight units using CCFLs. Also, when the point light sources are arranged in two dimension, the backlight units can sequentially turn on the light sources in synchronization with a scanning time of the LCD, thereby effectively avoiding motion blur that causes the afterimage phenomenon when one image is converted into another image in the LCD.

The backlight units that can turn on the light sources (e.g., LEDs) in synchronization with the scanning time of the LCD may be configured such that light output from one LED is uniformly emitted only to a predetermined region and not be diffused to other regions. For example, when a plurality of LEDs are arranged in two dimensions, one LED must uniformly emit light only to a region right over the backlight unit but may not emit light to other regions. To this end, a light emitting device for uniformly emitting light from an LED only to a specific region is required.

FIG. 1A is a sectional view of a conventional light emitting device 1. Referring to FIG. 1A, the conventional light emitting device 1 is made of transparent resin 2, and an LED device 3 is embedded in the transparent resin 2. A mirror 4 is attached to a bottom surface of the dome-shaped transparent resin 2. A top surface of the transparent resin 2 has a convex lens-shaped protruding surface formed at a central portion. A ring-shaped flat surface is formed around the central portion of the top surface of the transparent resin 2. The central protruding surface is a directly emitting surface 5 through which light emitted from the LED device 3 is emitted directly, and the circumferential flat surface is a totally reflecting surface 6 through which light emitted from the LED device 3 is reflected totally.

Referring to FIG. 1A, part of light emitted from the LED device 3 is directly vertically emitted upward through the directly emitting surface 5. The remaining part of the light emitted from the LED device 3 is totally reflected by the flat totally reflecting surface 6 and then reflected by the mirror 4 to be emitted vertically. In this structure, intermittent non-emission regions through which light is not emitted are produced. FIG. 1B is a graph illustrating the distribution of light emitted by the light emitting device 1. The brightest light is emitted through, the directly emitting surface 5, and non-emission regions through which light is not emitted are concentrically formed around the directly emitting surface 5.

FIG. 2A is a sectional view of a modified example of the conventional light emitting device to solve the problem. Referring to FIG. 2A, a light emitting device 28 is made of transparent resin 12, and an LED device 13 is embedded in the transparent resin 12. A bottom surface of the light emitting device 28 is divided into three mirrors 29a through 29c, and a top surface of the light emitting device 28 is flat and has a ring-shaped groove 26 formed around a central portion thereof. The central mirror 29a has a hemispheric shape, and the other mirrors 29b and 29c have a ring-shape with a curved surface. The central portion of the top surface of the light emitting device 28 is a directly emitting surface 15 through which light is emitted directly, and a portion formed around the groove 26 is a totally reflecting surface 16 by which light is reflected totally.

In this structure, part of light emitted from the LED device 13 passes through the central directly emitting surface 15 to be directly vertically emitted upward. Another part of the light emitted from the LED device 13 is totally reflected by a wall surface formed between the directly emitting surface 15 and the groove 26, and then reflected by the second mirror 29b to be emitted vertically upward. Another part of the light emitted from the LED device 13 is totally reflected by the groove 26 and then reflected by the second mirror 29b to be emitted vertically, or is totally reflected by the totally reflecting surface 16 and then reflected by the third mirror 29c to be emitted vertically. Meanwhile, a small amount of light horizontally emitted from the LED device 13 is reflected by the first mirror 29a and then transmitted through the directly emitting surface 15 to be emitted.

However, the modified light emitting device 28 also has a problem in that light is not emitted through some regions. For example, no light or a small amount of light is emitted through edge portions of the mirrors, that is, portions marked by dotted circles in FIG. 2A. As a result, non-emission regions having a concentric circle shape marked by oblique lines in FIG. 2B are produced. Also, the amount of light decreases from the central portion to edges of the light emitting device 28 of FIG. 2A. Consequently, when the light emitting device 28 is cut into a rectangular shape to achieve a backlight unit in which light sources are arranged in two dimensions, corner regions of the light emitting device 28 marked by oblique lines are darker than other portions.

### SUMMARY OF THE INVENTION

The present invention provides a light emitting device that can uniformly emit light within a specific region.

The present invention also provides a backlight unit that uses the light emitting device to sequentially turn on light sources according to a scanning time of a liquid crystal display.

According to an aspect of the present invention, there is provided a light emitting device comprising: a light reflecting member having light reflecting surfaces by which light is reflected; a light transmitting member formed on the light reflecting surfaces of the light reflecting member and having light emitting surfaces; and a point light source emitting light to the light transmitting member, wherein the light emitting surfaces of the light transmitting member through which light incident from the point light source is emitted comprise: a flat directly emitting surface facing the point light source, and directly passing light emitted from the point light source to an outside of the light transmitting member; and a curved totally reflecting surface formed around the directly emitting surface, and which totally reflects light emitted from the point light source to the light reflecting member and passing light reflected by the light reflecting member to the outside of the light transmitting member.

The light reflecting surfaces of the light reflecting member may be inclined to reflect to the totally reflecting surface both light directly incident from the point light source and light totally reflected by and incident from the totally reflecting surface. Each of the light reflecting surfaces of the light reflecting member may have a rectangular cross section whose width increases upward. The light reflecting member may have a rectangular flat bottom surface.

The totally reflecting surface may have a height that increases away from the directly emitting surface. The totally reflecting surface may have a radius of curvature that increases away from the directly emitting surface. The directly emitting surface may have a circular shape, and the circumference of the totally reflecting surface has a rectangular cross section.

The point light source may be disposed at the center of the light reflecting surfaces and surrounded by a lower portion of the light transmitting member. The point light source may be a laser diode or a light emitting diode.

According to another aspect of the present invention, there is provided a backlight unit comprising: a base substrate; and a plurality of light emitting devices arranged in a two dimensional array on the base substrate, wherein each of the light emitting devices comprises: a light reflecting member having light reflecting surfaces by which light is reflected; a point light source disposed at the center of the light reflecting surfaces of the light reflecting member and emitting light; and a light transmitting member formed on the light reflecting surfaces of the light reflecting member and the point light source and having light emitting surfaces through which light incident from the point light source is emitted, wherein the light emitting surfaces of the light transmitting member comprise: a flat directly emitting surface facing the point light source, and directly passing light emitted from the point light source to an outside of the light transmitting member; and a curved totally reflecting surface formed around the directly emitting surface, and which totally reflects light emitted from the point light source to the light reflecting member and passing light reflected by the light reflecting member to the outside of the light transmitting member.

The backlight unit may further comprise a diffusion plate uniformly diffusing light emitted from the light emitting devices.

The plurality of light emitting devices arranged in the two dimensional array may form a plurality of lines that sequentially emit light at predetermined time intervals.

The backlight unit may further comprise a plurality of parallel partitions formed on the base substrate and separating light emitted from light emitting devices forming one line, among the plurality of light emitting devices arranged in the two dimensional array, from light emitted from light emitting devices forming other line.

### BRIEF DESCRIPTION OF THE DRAWINGS

The above and other features and advantages of the present invention will become more apparent by describing in detail exemplary embodiments thereof with reference to the attached drawings, in which:

FIG. 1A is a sectional view of a conventional light emitting device;

FIG. 1B is a graph illustrating the distribution of light emitted by the conventional light emitting device of FIG. 1A;

FIG. 2A is a sectional view of another conventional light emitting device;

FIG. 2B is a top plan view illustrating dark regions produced in the conventional light emitting device of FIG. 2A;

FIGS. 3A through 3C illustrate a light emitting device according to an embodiment of the present invention;

FIGS. 4A and 4B illustrate paths through which light emitted from the light emitting device of FIGS. 3A through 3C is emitted;

FIG. 5 illustrates simulation results of the distribution of light emitted from the light emitting device of FIGS. 3A through 3C;

FIGS. 6A and 6B illustrate a backlight unit according to an embodiment of the present invention; and

FIG. 7 is a sectional view of a backlight unit according to another embodiment of the present invention.

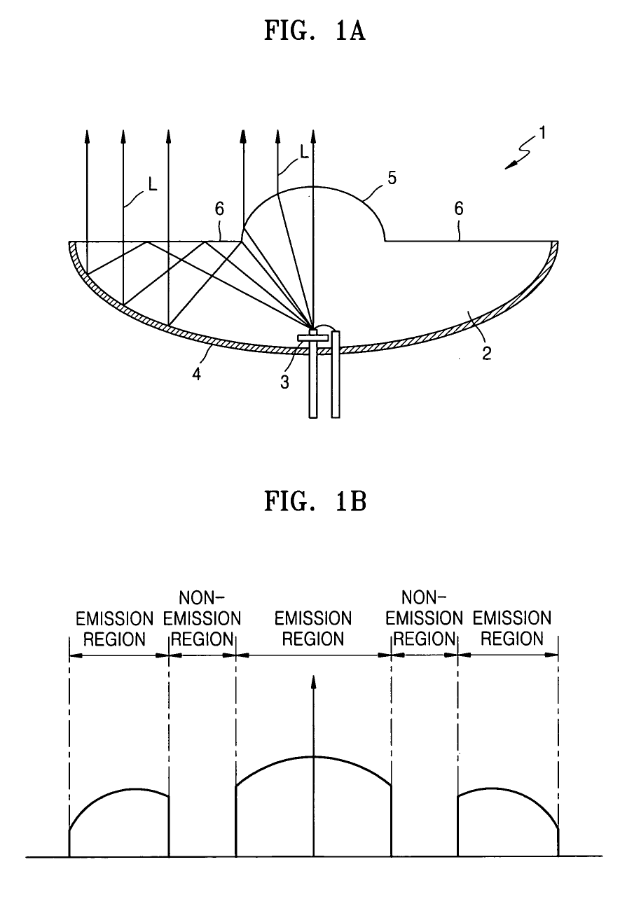

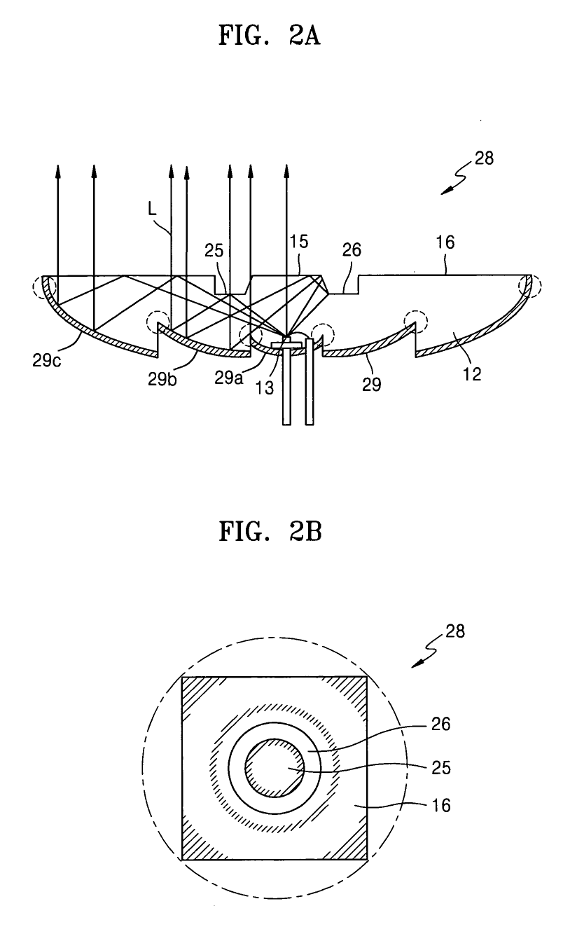

### DETAILED DESCRIPTION OF THE INVENTION

The present invention will now be described more fully with reference to the accompanying drawings, in which exemplary embodiments of the invention are shown.

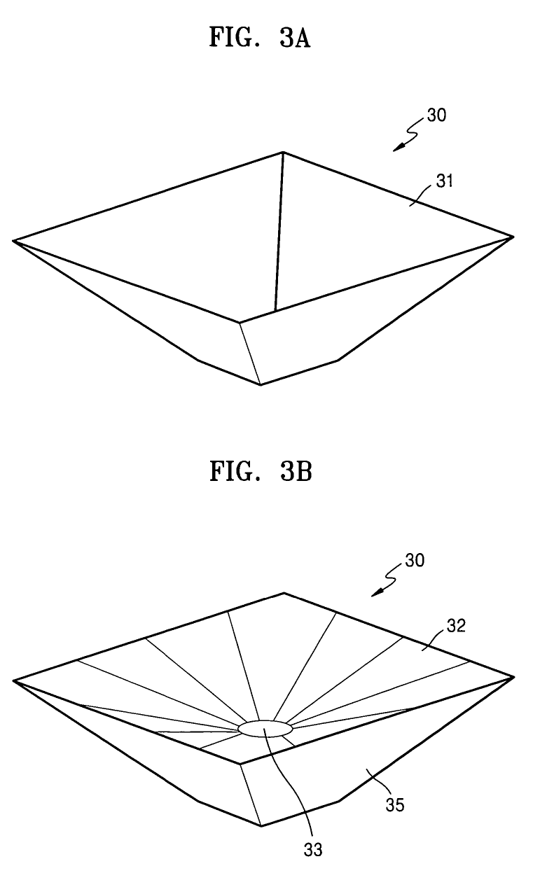

FIGS. 3A through 3C illustrate a light emitting device according to an exemplary embodiment of the present invention. FIG. 3A is a perspective view of a light reflecting member of the light emitting device. FIG. 3B is a perspective view of a light transmitting member of the light emitting device. FIG. 3C is a vertical sectional view of the light emitting device.

Referring to FIG. 3A, a light emitting device 30 includes a light reflecting member 31 having four inclined light reflecting surfaces. Each of the four inclined light reflecting surfaces has a rectangular cross section whose width increases upward. Also, the light reflecting member 31 may have a rectangular flat bottom surface. Accordingly, the light reflecting member 31 looks like an inverted pyramid whose vertex is cut horizontally.

Referring to FIG. 3B, the light emitting device 30 includes a light transmitting member 35 having a bottom surface and side surfaces that conform to the reflecting surfaces of the light reflecting member 31. For example, the light transmitting member 35 may be made of transparent resin such as emulsion polymethyl-methacrylate (PMMA). In the present embodiment, a top surface of the light transmitting member 35 is divided into two portions, that is, a flat circular directly emitting surface 33 formed at a central portion and a curved totally reflecting surface 32 formed around the directly emitting surface 33. The circumference of the totally reflecting surface 32 has a rectangular cross section whose height increases outward. Accordingly, the top surface of the light transmitting member 35 has a hollow shape whose height decreases inwardly and is lowest at the directly emitting surface 33.

Referring to FIG. 3C, the light emitting device 30 includes the light reflecting member 31 having the light reflecting surfaces by which light is reflected, the light transmitting member 35 formed on the light reflecting surfaces of the light reflecting member 31, and a point light source 34 emitting light to the light transmitting member 35. The point light source 34 is disposed at the center of the inner light reflecting surfaces of the light reflecting member 31 and is surrounded by a lower portion of the light transmitting member 35. Accordingly, light emitted from the point light source 34 is incident on the lower portion of the light transmitting member 35 and emitted through the top surface of the light transmitting member 35. The point light source 34 may be a light emitting element such as a laser diode (LD) or a light emitting diode (LED).

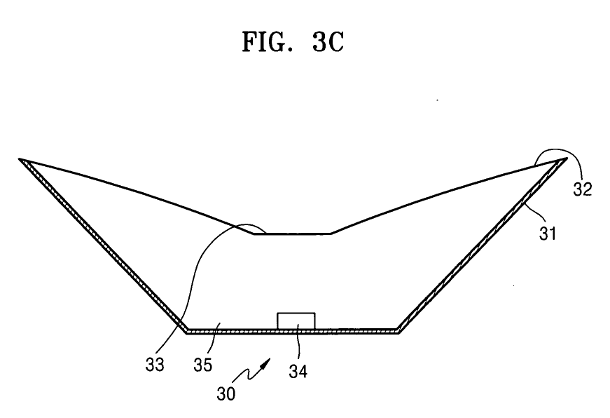

FIGS. 4A and 4B illustrate paths through which light emitted from the light emitting device 30 is emitted. FIG. 4A illustrates that Lambertian light emitted from the point light source 34 is uniformly emitted from the light transmitting member 35 by the light emitting device 30. FIG. 4B illustrates three paths through which light is emitted in the light emitting device 30.

Referring to FIG. 4B, light L₁ incident on the directly emitting surface 33, among lights emitted from the point light source 34, is directly emitted to the outside of the light transmitting member 35. If the directly emitting surface 33 is too large, light may be totally reflected at an edge of the directly emitting surface 33. Accordingly, the directly emitting surface 33 should be formed so that the incident angle of light incident to the edge of the directly emitting surface 33 from the point light source 34 can be less than a critical angle. The size of the directly emitting surface 33 can be determined by a distance between the directly emitting surface 33 and the point light source 34 and a refractive index of the light transmitting member 35.

In the meantime, since light emitted from the point light source 34 is Lambertian light that is diffused over large areas, part of the light emitted from the point light source 34 is incident on the totally reflecting surface 32 and the light reflecting surfaces of the light reflecting member 31. Since light L₂ is incident on the totally reflecting surface 32 at an angle greater than the critical angle, the light L₂ is totally reflected by the totally reflecting surface 32 to be directed toward the light reflecting surfaces of the light reflecting member 31, and then is reflected by the light reflecting surfaces of the light reflecting member 31 to be directed toward the totally reflecting surface 32. Here, since the light reflected by the light reflecting surfaces of the light reflecting member 31 is incident on the totally reflecting surface 32 at an angle less than the critical angle, the light is emitted to the outside of the light transmitting member 35. Also, light L₃ emitted at a relatively great angle from the point light source 34 propagates toward the light reflecting member 31, is reflected by the light reflecting surfaces of the light reflecting member 31, and is incident on the totally reflecting surface 32. As described above, since the light reflected by the light reflecting surfaces of the light reflecting member 31 is incident on the totally reflecting surface 32 at an angle less than the critical angle, the light can be directly emitted to the outside of the light transmitting member 35 without total reflection.

Referring to FIG. 4A, Lambertian light emitted from the point light source 34 is uniformly emitted from the light transmitting member 35 by the light emitting device 30. The Lambertian light emitted from the point light source 34 has a brightness that is highest at a central portion and decreases outward. The brightest central light is directly emitted through the directly emitting surface 33 to the outside of the light transmitting member 35. Here, since a refractive index of the outside is less than the refractive index of the light transmitting member 35, a divergence angle increases slightly in the outside. The fainter light around the central light is totally reflected by the totally reflecting surface 32, reflected by the light reflecting surfaces of the light reflecting member 31, and emitted through the totally reflecting surface 32 to the outside of the light transmitting member 35. As shown in FIG. 4A, most of the reflected and emitted light is directed around the directly emitted light. Also, part of the light emitted at the greatest angle from the point light source 34 has a lowest intensity such that it is reflected by the light reflecting surfaces of the light reflecting member 31 and emitted through the totally reflecting surface 32 to the outside of the light transmitting member 35. The light emitted at the greatest angle from the point light source 34, reflected by the light reflecting member 31, and then emitted to the outside of the light transmitting member 35 is also directed around the directly emitted light to be combined with the light totally reflected by the totally reflecting surface 32, reflected by the light reflecting member 31, and emitted through the totally reflecting surface 32, thereby increasing the intensity. Accordingly, the light emitted from the light transmitting member 35 has a uniform intensity without dark regions. Further, the light is emitted upward from the light transmitting member 35, but is not diffused to an edge portion of the light transmitting member 35. Therefore, the light can be uniformly emitted to a specific region over the light transmitting member 35.

To enable the light emitted to the edge portion of the light transmitting member 35 to have a uniform high intensity, a larger amount of light than that of light used in the conventional art needs to be emitted to the edge portion of the light transmitting member 35 to be totally reflected. To this end, the totally reflecting surface 32 may have a curved shape, and a radius of curvature of the totally reflecting surface 32 increases away from the directly emitting surface 33.

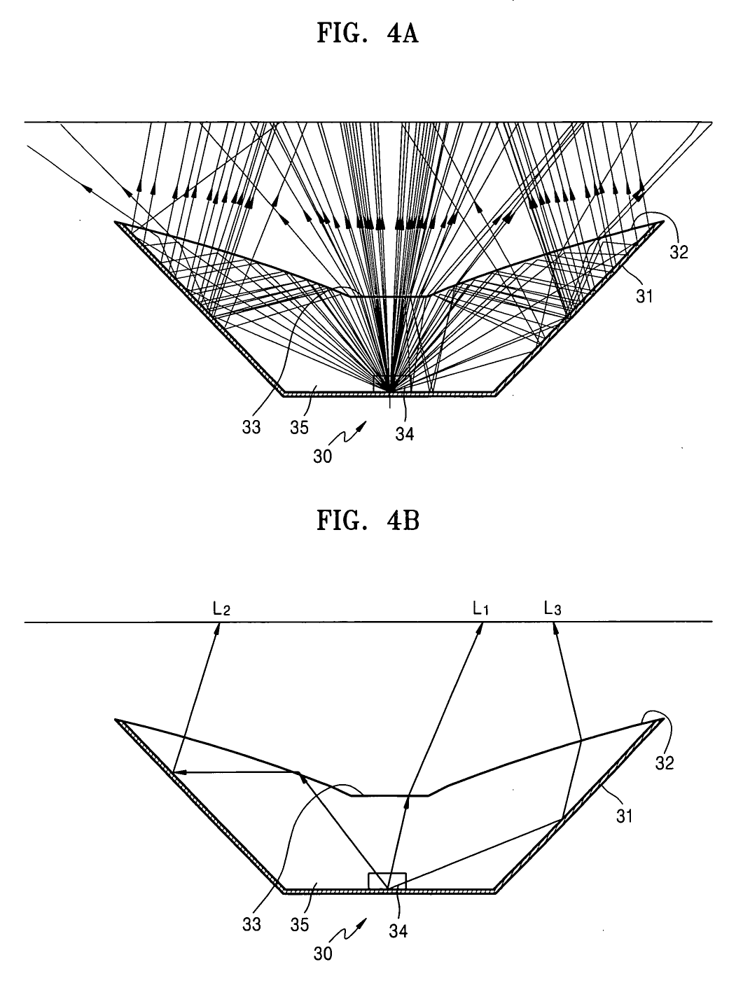

FIG. 5 illustrates simulation results of the distribution of light emitted from the light emitting device 30. An inner portion of a square box 40 is a portion over the light emitting device 30 and an outer portion of the square box 40 is the vicinity of the light emitting device 30. Referring to FIG. 5, while the portion over the light emitting device 30 has a uniform high intensity of light, light is barely diffused to the vicinity of the light emitting device 30.

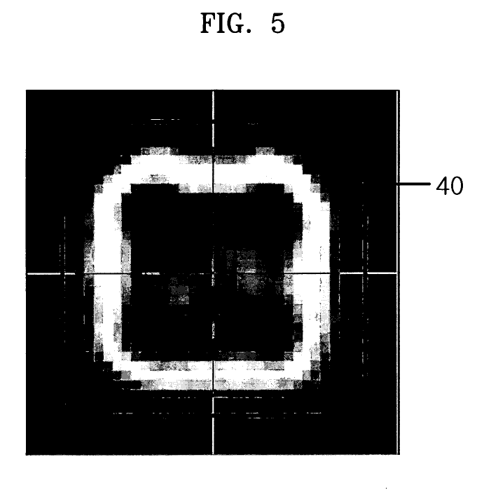

A backlight unit employing the light emitting device 30 can sequentially emit light according to a scanning time of a liquid crystal display (LCD) without light diffusion to the vicinity. FIGS. 6A and 6B illustrate a backlight unit 40 employing the light emitting devices 30 according to an exemplary embodiment of the present invention. FIG. 6A is a sectional view of the backlight unit 40. FIG. 6B illustrates light emitting devices 30 that are arranged in a two dimensional array in the backlight unit 40.

Referring to FIGS. 6A and 6B, a plurality of light emitting devices 30 arranged in a two dimensional array are mounted on a base substrate 41, and a diffusion plate 45 is installed over the light emitting devices 30 to uniformly diffuse light emitted from the light emitting devices 30. Here, each of the light emitting devices 30 has the same structure as the light emitting device 30 illustrated in FIGS. 3A through 3C. That is, a light transmitting member 35 is formed on a light reflecting member 31 that has inclined light reflecting surfaces each with a rectangular cross section, and a point light source 34, such as an LD or LED, is disposed on a central portion of the light reflecting member 31. Light emitting surfaces of the light transmitting member 35 through which light incident from the point light source 34 is emitted include a flat directly emitting surface 33 through which light emitted from the point light source 34 is directly transmitted to the outside of the light transmitting member 35, and a curved totally reflecting surface 32 by which light emitted from the point light source 34 is totally reflected to the light reflecting member 31.

Referring to FIG. 6B, the plurality of light emitting devices 30 arranged in the two dimensional array form a plurality of parallel lines 30a, 30b, 30c, . . . . In this backlight unit 40, light emitting devices forming one line can be turned on and off simultaneously, and can sequentially emit light at predetermined time intervals according to a scanning time of an LCD (not shown). For example, light emitting devices forming a first line 30a are turned on simultaneously to emit light for a predetermined period of time and then are turned off. Subsequently, light emitting devices forming a second line 30b are turned on simultaneously to emit light for a predetermined period of time and then turned off. Accordingly, motion blur, a serious problem of the conventional LCD, can be effectively prevented.

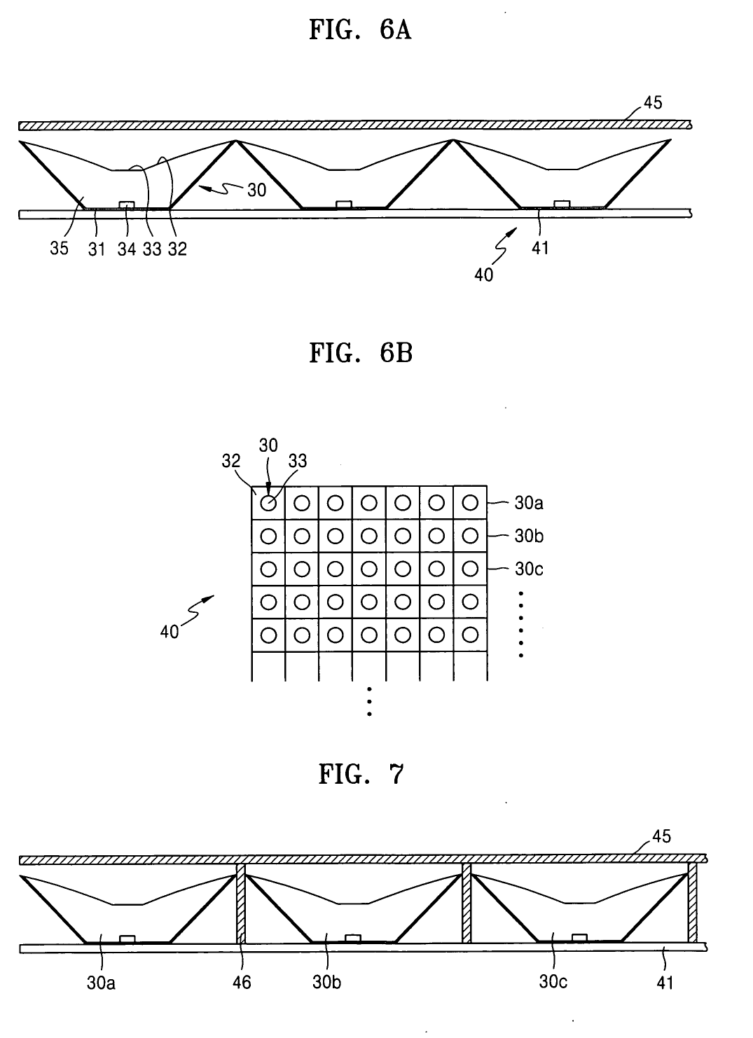

As described above, light is barely diffused to adjacent lines using the light emitting devices 30. To surely prevent light from being diffused to adjacent lines, the backlight unit 40 illustrated in FIGS. 6A and 6B may further include partitions each of which is installed between adjacent lines. FIG. 7 is a sectional view of a backlight unit according to another embodiment of the present invention. Referring to FIG. 7, to separate light emitted from light emitting devices forming one line, among light emitting devices arranged in a two dimensional array, from light emitted from light emitting devices forming another line, a plurality of partitions 46 may be installed on the base substrate 41. For example, referring to FIG. 6B, the plurality of parallel partitions 46 may be formed between the first line 30a and the second line 30b and between the second line 30b and the third line 30c. The partitions 46 can surely prevent light emitted from the first line 30a from being diffused to the second line 30b.

As described above, the light emitting device according to the present invention uniformly emits light without producing dark portions. Accordingly, the light emitting device can uniformly emit light within a predetermined region.

Furthermore, the backlight unit employing the light emitting device that emits light uniformly can sequentially emit light according to a scanning time of an LCD without light diffusion to adjacent lines. Accordingly, the backlight unit according to the present invention can effectively avoid motion blur that is a serious problem of the conventional LCD.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A light emitting device comprising:
a light reflecting member having light reflecting surfaces by which light is reflected;
a light transmitting member formed on the light reflecting surfaces of the light reflecting member and having light emitting surfaces; and
a point light source emitting light to the light transmitting member,
wherein the light emitting surfaces of the light transmitting member through which light incident from the point light source is emitted comprise:
a flat directly emitting surface facing the point light source, and directly passing light emitted from the point light source to an outside of the light transmitting member; and
a curved totally reflecting surface formed around the directly emitting surface, and which totally reflects light emitted from the point light source to the light reflecting member and passing light reflected by the light reflecting member to the outside of the light transmitting member.

2. The light emitting device of claim 1, wherein the light reflecting surfaces of the light reflecting member are inclined to reflect to the totally reflecting surface both light directly incident from the point light source and light totally reflected by and incident from the totally reflecting surface.

3. The light emitting device of claim 2, wherein each of the light reflecting surfaces of the light reflecting member has a rectangular cross section whose width increases upward.

4. The light emitting device of claim 3, wherein the light reflecting member has a rectangular flat bottom surface.

5. The light emitting device of claim 2, wherein the totally reflecting surface has a height that increases away from the directly emitting surface.

6. The light emitting device of claim 5, wherein the totally reflecting surface has a radius of curvature that increases away from the directly emitting surface.

7. The light emitting device of claim 5, wherein the directly emitting surface has a circular shape, and the circumference of the totally reflecting surface has a rectangular cross section.

8. The light emitting device of claim 5, wherein the point light source is disposed at the center of the light reflecting surfaces and surrounded by a lower portion of the light transmitting member.

9. The light emitting device of claim 8, wherein the point light source is a laser diode or a light emitting diode.

10. A backlight unit comprising:
a base substrate; and
a plurality of light emitting devices arranged in a two dimensional array on the base substrate,
wherein each of the light emitting devices comprises:
a light reflecting member having light reflecting surfaces by which light is reflected;
a point light source disposed at the center of the light reflecting surfaces of the light reflecting member and emitting light; and
a light transmitting member formed on the light reflecting surfaces of the light reflecting member and the point light source and having light emitting surfaces through which light incident from the point light source is emitted,
wherein the light emitting surfaces of the light transmitting member comprise:
a flat directly emitting surface facing the point light source, and directly passing light emitted from the point light source to an outside of the light transmitting member; and
a curved totally reflecting surface formed around the directly emitting surface, and which totally reflects light emitted from the point light source to the light reflecting member and passing light reflected by the light reflecting member to the outside of the light transmitting member.

11. The backlight unit of claim 10, wherein the light reflecting surfaces of the light reflecting member are inclined to reflect to the totally reflecting surface both light directly incident from the point light source and light totally reflected by and incident from the totally reflecting surface.

12. The backlight unit of claim 11, wherein each of the light reflecting surfaces of the light reflecting member has a rectangular cross section whose width increases upward.

13. The backlight unit of claim 12, wherein the light reflecting member has a rectangular flat bottom surface.

14. The backlight unit of claim 11, wherein the totally reflecting surface has a height that increases away from the directly emitting surface.

15. The backlight unit of claim 14, wherein the totally reflecting surface has a radius of curvature that increases away from the directly emitting surface.

16. The backlight unit of claim 14, wherein the directly emitting surface has a circular shape, and the circumference of the totally reflecting surface has a rectangular cross section.

17. The backlight unit of claim 14, wherein the point light source is a laser diode or a light emitting diode.

18. The backlight unit of claim 14, further comprising a diffusion plate uniformly diffusing light emitted from the light emitting devices.

19. The backlight unit of claim 14, wherein the plurality of light emitting devices arranged in the two dimensional array form a plurality of lines that sequentially emit light at predetermined time intervals.

20. The backlight unit of claim 18, further comprising a plurality of parallel partitions formed on the base substrate and separating light emitted from light emitting devices forming one line, among the plurality of light emitting devices arranged in the two dimensional array, from light emitted from light emitting devices forming another line.
